(19) United States
(12) Patent Application Publication
(10) Pub. No.: US 2017/0030778 A1
(43) Pub. Date: Feb. 2, 2017

(54) METHOD AND APPARATUS FOR CALCULATING THE JUNCTION TEMPERATURE OF AN RF POWER MOSFET

(71) Applicant: KONINKLIJKE PHILIPS N.V., EINDHOVEN (NL)

(72) Inventors: KEQIU ZENG, SUZHOU (CN); TAO WANG, SHANGHAI (CN); KAILAS SENAN, BANGALORE (IN)

(21) Appl. No.: 15/122,955

(22) PCT Filed: Mar. 3, 2015
(86) PCT No.: PCT/EP2015/054343

§ 371 Date: Sep. 1, 2016

(30) Foreign Application Priority Data
Mar. 4, 2013 (CN) PCT/CN2014/072868
Jun. 16, 2014 (EP) 14172563.0

(51) Int. Cl. G01K 7/01; G01R 33/36

(52) U.S. Cl. CPC G01K 7/01; G01R 33/3614

(57) ABSTRACT

There are provided a method and apparatus for calculating the junction temperature of an RF power MOSFET. The method for calculating the junction temperature of an RF power MOSFET, comprising steps of: establishing a transient thermal impedance model of the RF power MOSFET in analog domain; calculating a transfer function in time domain of the transient thermal impedance model using bilinear transformation; establishing a junction temperature compensation model in digital domain based on the transfer function in time domain of the transient thermal impedance model with a sampling frequency and a type of 2^{nd} order IIR filter structure; and calculating the junction temperature of the RF power MOSFET by inputting an actual input to the junction temperature compensation model. The present invention improves accuracy in determining the junction temperature of an RF power MOSFET.

### FIELD OF THE INVENTION

The invention relates to semiconductor temperature measurement, in particular relates to a method and apparatus for calculating the junction temperature of an RF power MOSFET.

### BACKGROUND OF THE INVENTION

Radio frequency (RF) metallic oxide semiconductor field effect transistors (MOSFETs) are the most important elements in a magnetic resonance imaging (MRI) amplifier. Most of the MRI failure is caused by MOSFETs, and most of the MOSFET failure is caused by internal overheat of junction temperature of MOSFETs. Thus, it is essential to detect junction temperature of MOSFETs in an accurate and fast way to ensure the MRI amplifier working well. However, because the MOSFETs are sealed in packages, it is impossible to detect junction temperature directly with thermoprobes or infrared detectors.

The solution for solving the above problem in the prior art is analog simulation. That is, though it is impossible to detect junction temperature directly with thermoprobes or infrared detectors, the junction temperature of an MOSFET can be derived by establishing a transient thermal impedance model which is equivalent to the MOSFET and then inputting an actual input signal with an actual power to transient thermal impedance model. The output of the transient thermal impedance model represents the junction temperature of the MOSFET.

In the prior art, there are many ways for establishing the transient thermal impedance model which is equivalent to the MOSFET. FIG. 1a shows a typical MOSFET heat dissipation structure and FIG. 1b shows its equivalent transient thermal impedance model in the prior art.

As shown in FIG. 1a, heat generated within a junction 101 in a silicon chip 102 of the MOSFET is typically dissipated to a case 103, a heat sink 104 and ambient surroundings 105. Temperature loss from junction 101 to case 103 is considered here for thermal impedance estimation. Temperature loss from case 103 to heat sink 104 and from heat sink 104 to ambient surroundings 105 are ignored and set to zero.

FIG. 1b shows an equivalent transient thermal impedance model of the structure of FIG. 1a. The input of the equivalent transient thermal impedance model is the actual dissipated power P_{DM} in the MOSFET, and the output is the junction temperature T_{J}, which is calculated from the below equation.

T_{J}=×T_{JC}+T_{C}

=(P_{DM}×Z_{qJC})+T_{C}

### Where,

T_{J}—Junction Temperature (° C.)
T_{C}—Case Temperature (° C.)
ΔT_{JC}—Temperature transferred from Junction to Case
P_{DM}—Dissipation Power of the MOSFET (Watts)
Z_{qJC}—Junction-to-Case Thermal Impedance (° C./watts)

Initially, when the MOSFET is not used, i.e. the P_{DM} is not applied, the ΔT_{JC}=0 and T_{J}=T_{C}. After the P_{DM} is applied, heat is transferred from the junction to the case and the junction temperature T_{J} is increased by ΔT_{JC}, which is equal to result of multiplying P_{DM} by Junction-to-Case Thermal Impedance Z_{qJC}. Z_{qJC} is analogue to electrical impedance in the electrical field. Z_{qJC} is defined by a ratio of increased temperature to the applied power, which is increased temperature (° C.) per 1 walt applied, while the electrical impedance is defined by a ratio of a voltage to a current, which is increased voltage (V) per 1 ampere applied. R₁, R₂, C₁, C₂ in FIG. 1b are all thermal resistors or thermal capacitors, not electrical resistors or electrical capacitors. Different MOSFETs have different values of R₁, R₂, C₁, C₂, which are calculated when out of factories and usually listed in the product specification. Z_{EXT} in FIG. 1b represents external thermal impendence including case-to-sink thermal impendence and sink-to-ambient thermal impendence, which are usually set to zero. Thus, an analog circuit which is analog to the equivalent transient thermal impedance model in FIG. 1b can be established, which has electrical resistors and electrical capacitors with the same ohm values as the thermal resistors and the thermal capacitors and current value of the current source with the same ampere values with P_{DM}. Then the volt value of the voltage across the current source is the same with the ° C. value of T_{J}, and thus T_{J} can be read from the measured volt value of the voltage across the current source.

The drawback of the above analog circuit solution is low accuracy due to low precision of actual electrical elements such as electrical resistors and electrical capacities adopted in the analog circuit. If the electrical elements such as electrical resistors and electrical capacities are selected and tested in high accuracy, time cost is high.

Maxat N. Touzelbaev, etc. “High-efficiency transient temperature calculations for applications in dynamic thermal management of electronic devices”, and US2012/278029 A1, disclose a method for calculating transient temperature based on resistor-capacitor (RC) network which is converted into a 1^{st} order infinite impulse response (IIR) digital filter.

### SUMMARY OF THE INVENTION

Based on understanding of the technical problems and prior art described above, it will be desirable to determine the junction temperature of an RF power MOSFET in high accuracy and acceptable time cost.

According to one aspect of this invention, there is provided a method for calculating the junction temperature of an RF power MOSFET, comprising steps of: establishing a transient thermal impedance model of the RF power MOSFET in analog domain; calculating a transfer function in time domain of the transient thermal impedance model using bilinear transformation; establishing a junction temperature compensation model in digital domain based on the transfer function in time domain of the transient thermal impedance model with a preferable sampling frequency and a type of 2^{nd} order IIR filter structure; and calculating the junction temperature of the RF power MOSFET by inputting an actual input to the junction temperature compensation model.

Because this invention does not adopt an analog circuit solution, and instead, establishes a junction temperature compensation model in digital domain, which can be realized logically by software or firmware without physically establishing actual analog circuits, it removes influence due to low precision of actual electrical elements adopted in the analog circuit and thus improves accuracy of determining the junction temperature of an RF power MOSFET.

Optionally, the preferable sampling frequency is selected as 10 KHz. Optionally, the type of 2^{nd} order IIR filter structure is selected as direct form II IIR filter structure.

The 10 KHz sampling frequency and the direct form II IIR filter structure can help further improve accuracy of determining the junction temperature of an RF power MOSFET, which are proved by simulation results.

According to another aspect of this invention, there is provided an apparatus for calculating the junction temperature of an RF power MOSFET, comprising: a first establishing unit configured to establish a transient thermal impedance model of the RF power MOSFET in analog domain; a first calculating unit configured to calculate a transfer function in time domain of the transient thermal impedance model using bilinear transformation; a second establishing unit configured to establish a junction temperature compensation model in digital domain based on the transfer function in time domain of the transient thermal impedance model with a preferable sampling frequency and a type of 2^{nd} order IIR filter structure; and a second calculating unit configured to calculate the junction temperature of the RF power MOSFET by inputting an actual input to the junction temperature compensation model.

According to another aspect of this invention, there is provided a computer executable program recorded in a computer readable medium and which can be executed by a computer to perform a method for calculating the junction temperature of an RF power MOSFET when loaded to the computer, comprising instruction codes of: establishing a transient thermal impedance model of the RF power MOSFET in analog domain; calculating a transfer function in time domain of the transient thermal impedance model using bilinear transformation; establishing a junction temperature compensation model in digital domain based on the transfer function in time domain of the transient thermal impedance model with a sampling frequency and a type of 2^{nd} order IIR filter structure; and calculating the junction temperature of the RF power MOSFET by inputting an actual input to the junction temperature compensation model.

According to another aspect of this invention, there is provided a magnetic resonance imaging (MRI) system comprising a MRI amplifier, the MRI system further comprises the apparatus for calculating the junction temperature of at least one RF power MOSFET used in the MRI amplifier.

These and other aspects of the invention will be apparent from and elucidated with reference to the embodiments described hereinafter.

### DESCRIPTION OF THE DRAWINGS

The above and other objects and features of the present invention will become more apparent from the following detailed description considered in connection with the accompanying drawings, in which:

FIG. 1a shows atypical MOSFET heat dissipation structure and FIG. 1b shows its equivalent transient thermal impedance model in the prior art;

FIG. 2 shows a flow chart of a method for calculating the junction temperature of an RF power MOSFET according to an embodiment of this invention;

FIG. 3 shows a detailed flow chart of step S2 in FIG. 2 according to an embodiment of this invention;

FIG. 4 shows a detailed flow chart of step S3 in FIG. 2 according to an embodiment of this invention;

FIG. 5 shows an example of a direct form II IIR filter structure selected for establishing the junction temperature compensation model according to an embodiment of this invention; and

FIG. 6 shows a block figure of an apparatus for calculating the junction temperature of an RF power MOSFET according to an embodiment of this invention.

The same reference numerals are used to denote similar parts throughout the figures.

### DETAILED DESCRIPTION

Detailed description of the present invention is given below in connection with the accompanying drawings.

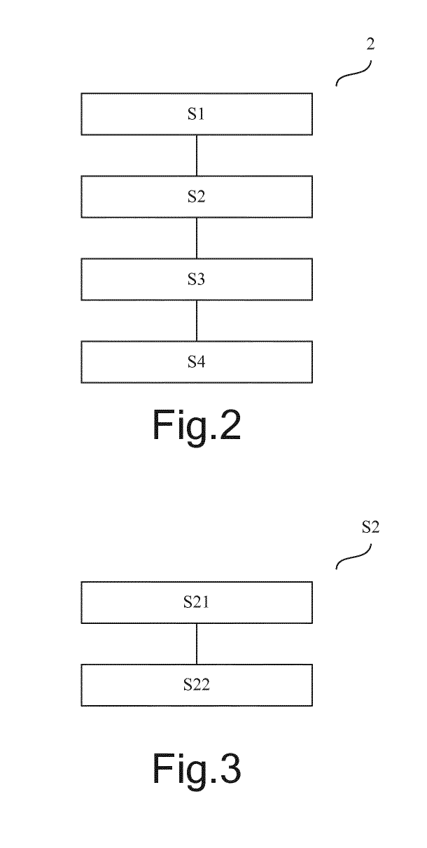

FIG. 2 shows a flow chart of a method for calculating the junction temperature of an RF power MOSFET according to an embodiment of this invention.

According to an embodiment of this invention, a method 2 for calculating the junction temperature of an RF power MOSFET is provided.

The method 2 for calculating the junction temperature of an RF power MOSFET can be used to calculating the junction temperature of any kind of RF power MOSFET, including a medical instrument specific RF power MOSFET or non-medical instrument specific RF power MOSFET, an RF power MOSFET in an MRI amplifier or an RF power MOSFET in other electrical elements. Because MOSFETs are the most critical elements in an MRI amplifier, the method 2 may have a better applying prospect for the RF power MOSFETs in an MRI amplifier.

The method 2 can be realized by an embedded component which is embedded into the instrument where the RF power MOSFET is incorporated, or by an independent device such as a general computer loaded with corresponding software.

As seen from FIG. 2, the method 2 comprises step S1 of establishing a transient thermal impedance model of the RF power MOSFET in analog domain.

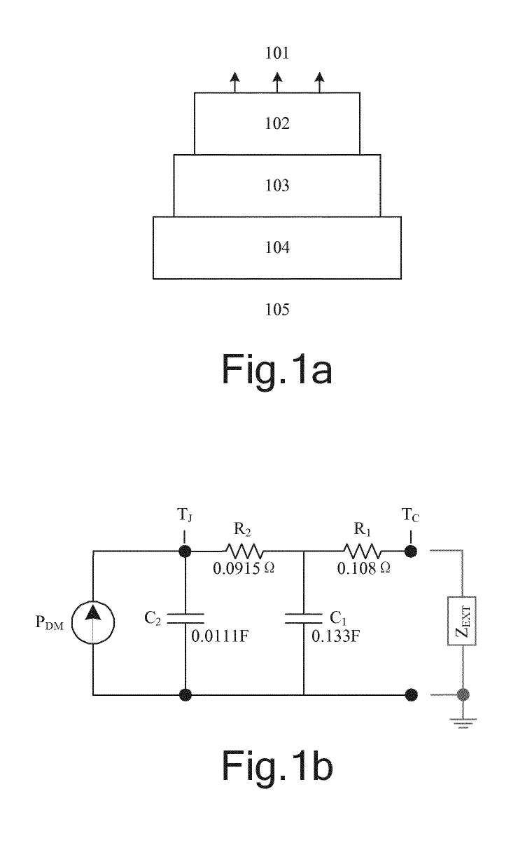

The transient thermal impedance model of the RF power MOSFET (as in FIG. 1b) can be established in many ways. For example, as stated in the above background portion, R₁, R₂, C₁, C₂, etc. are calculated when out of factories and usually listed in the product specification, thus, the transient thermal impedance model of the RF power MOSFET can be established by means of inputting parameters such as R₁, R₂, C₁, C₂, etc. by an operator or automatically recognizing the scanned product specification by a general computer loaded with character recognizing software, etc. Another way for establishing a transient thermal impedance model of the RF power MOSFET is testing as the same with what is did when the MOSFET is out of factories if the product specification does not contain such information. There are many ways for such testing in the prior art.

The method 2 further comprises step S2 of calculating a transfer function in time domain of the transient thermal impedance model using bilinear transformation.

The transfer function of the transient thermal impedance model means output of the transient thermal impedance model, i.e. the junction temperature of the RF power MOSFET, divided by input of the transient thermal impedance model, i.e. the power generated when the RF power MOSFET works. Still taking FIG. 1b as example, the transfer function of the transient thermal impedance model can be represented as follows:

Z_{qJC}=((R₁∥C₁)+R₂)∥C₂+Z_{EXT}

wherein R₁, R₂, C₁, C₂ are thermal resistors or thermal capacitors, which are discussed in the background portion. Z_{EXT} is external thermal impendence, which is discussed also in the background portion and usually set to zero. If Z_{EXT} is set to zero, the transfer function of the transient thermal impedance model can be simplified as follows:

Z_{qJC}=((R₁∥C₁)+R₂)∥C₂.

The transfer function in time domain of the transient thermal impedance model can be computed in many ways. For example, it can be computed as in FIG. 3 by calculating a transfer function in frequency domain of the transient thermal impedance model in step S21 and converting the transfer function in frequency domain of the transient thermal impedance model into the transfer function in time domain of the transient thermal impedance model using bilinear transformation in step S22. Detailed procedure of step S21 and step S22 will be described later. As another example, the transfer function in time domain of the transient thermal impedance model can be computed directly by a known specific tool.

The bilinear transformation is a known method in signal processing for converting frequency domain representation (S plane) into time domain representation (Z plane).

The method 2 further comprises step S3 of establishing a junction temperature compensation model in digital domain based on the transfer function in time domain of the transient thermal impedance model with a preferable sampling frequency and a type of 2^{nd} order IIR filter structure.

The junction temperature compensation model means the model that will be used in calculating the junction temperature of an RF power MOSFET according to an embodiment of this invention.

The sampling frequency is a parameter of the transfer function in time domain of the transient thermal impedance model and thus only after the sampling frequency is fixed, the transfer function in time domain of the transient thermal impedance model is fixed. Any sampling frequency could be adopted if the sampling principle is satisfied. With a preferable sampling frequency satisfying the sampling principle, the accuracy in determining the junction temperature of an RF power MOSFET can be improved. The preferable sampling will be discussed later.

The junction temperature compensation model in digital domain can be established by common technology in signal processing based on the transfer function in time domain. Its structure is related to the type of 2^{nd} order IIR filter structure. With different types of 2^{nd} order IIR filter structures, the structures of established junction temperature compensation models are different. Though they can all improve accuracy in determining the junction temperature of an RF power MOSFET, the preferable type will be discussed later.

The method 2 further comprises step S4 of calculating the junction temperature of the RF power MOSFET by inputting an actual input to the junction temperature compensation model.

Here, the actual input means an input signal representing the monitored power generated when the RF power MOSFET works. After the junction temperature compensation model is realized by software or firmware simulation, with the actual input representing the power generated when the RF power MOSFET works, the output of the junction temperature compensation model realized by software or firmware simulation is the junction temperature of an RF power MOSFET. The power generated when the RF power MOSFET works can be computed by real-time monitoring the voltage and the current of the RF power MOSFET and multiplying the voltage and the current.

Because the junction temperature compensation model is in digital domain, it can be simulated by software or firmware without physically establishing the actual analog circuit, thus improving accuracy in determining the junction temperature of an RF power MOSFET. In software realization, step S4 is implemented by software simulation, i.e. the digital units in the junction temperature compensation model are realized as logical blocks by software. It can be realized by many ways. For example, it can be realized by Matlab Simulink tool. In firmware realization, step S4 is implemented by FPGA, i.e. the digital units in the junction temperature compensation model are realized as logical blocks but the logical blocks are respectively written to individual physical chips (hardwares). For example, it can be realized using JTAG hardware-in-loop simulation with Xilinx Spartan-6 FPGA development board.

Now let us discuss the detailed procedures of step S21 and step S22 in FIG. 3.

Step 21 of calculating a transfer function in frequency domain of the transient thermal impedance model can be performed as follows: assuming corresponding thermal impedance for a resistor R being R, corresponding thermal impedance for an inductor L being sL, corresponding thermal impedance for a capacitor C being 1/sC, the transfer function in frequency domain of the transient thermal impedance model, which is equal to the total thermal impedance of the transient thermal impedance model, can be thus calculated. Still taking FIG. 1b for example,

$$\begin{matrix}{H}_{( s )} = ( ( {R}_{1} ‖ {C}_{1} ) + {R}_{2} ) ‖ {C}_{2} \\ = ( ( {R}_{1} \times 1 / s {C}_{1} ) / ( {R}_{1} + 1 / {sC}_{1} ) + {R}_{2} ) ‖ {C}_{2} \\ = ( \frac{{R}_{1}}{1 + {sR}_{1} {C}_{1}} + {R}_{2} ) ‖ {C}_{2} \\ = ( \frac{{R}_{1} + {sR}_{1} {C}_{1} {R}_{2} + {R}_{2}}{1 + {sR}_{1} {C}_{1}} ) ‖ {C}_{2} \\ = \frac{( \frac{{R}_{1} + {sR}_{1} {C}_{1} {R}_{2} + {R}_{2}}{1 + {sR}_{1} {C}_{1}} )}{1 + s ( \frac{{R}_{1} + {sR}_{1} {C}_{1} {R}_{2} + {R}_{2}}{1 + {sR}_{1} {C}_{1}} ) {C}_{2}} \\ = \frac{{R}_{1} + {sR}_{1} {C}_{1} {R}_{2} + {R}_{2}}{1 + {sR}_{1} {C}_{1} + {sR}_{1} {C}_{2} + {s}^{2} {R}_{1} {C}_{1} {R}_{2} {C}_{2} + {sR}_{2} {C}_{2}}\end{matrix}$$

where s is the complex frequency, after substituting R₁, R₂, C₁, C₂ values into H₍ₛ₎,

$$\begin{matrix}{H}_{( s )} = \frac{0.108 + ( s 0.108 \times 0.133 \times 0.0915 ) + 0.0915}{\begin{matrix}1 + ( s 0.108 \times 0.133 ) + ( s 0.108 \times 0.0111 ) + \\ ( {s}^{2} 0.108 \times 0.133 \times 0.0915 \times 0.0111 ) + ( s 0.0915 \times 0.0111 )\end{matrix}} \\ = \frac{0.108 + 0.00131430 \; 6 s + 0.0915}{\begin{matrix}1 + 0.014364 s + 0.0011988 s + 0.00001458 \; 87966 {s}^{2} + \\ 0.00101565 s\end{matrix}} \\ = \frac{0.001314306 s + 0.1995}{0.0000145887966 {s}^{2} + 0.01657845 s + 1}\end{matrix}$$

Step S22 of converting the transfer function in frequency domain of the transient thermal impedance model into the transfer function in time domain of the transient thermal impedance model using bilinear transformation is performed as follows.

The bilinear transformation is a known method in signal processing for converting frequency domain representation (S plane) into time domain representation (Z plane). It first compresses a jΩ axis in an S plane into a section of a jΩ axis in an S1 plane so that the S plane is compressed into a band of the S1 plane, and then converts the band into the whole Z plane. Its advantage over other methods such as an impulse response constant method is removing aliasing due to frequency spectrum overlap, so it could be used in this invention to ensure high accuracy in determining the junction temperature of an RF power MOSFET.

By this method, the transfer function H_{(z)} in time domain of the transient thermal impedance model can be obtained by substituting

$$s = \frac{2 {f}_{s} ( Z - 1 )}{( Z + 1 )}$$

into H₍ₛ₎. Still taking the above example,

$$\begin{matrix}{H}_{( z )} = {H}_{( s )} {\vert}_{s = \frac{2 {f}_{s} ( Z - 1 )}{( Z + 1 )}} \\ = \frac{0.001314306 ( \frac{2 {f}_{s} ( Z - 1 )}{( Z + 1 )} ) + 0.1995}{\begin{matrix}0.0000145887966 {( \frac{2 {f}_{s} ( Z - 1 )}{( Z + 1 )} )}^{2} + \\ 0.01657845 ( \frac{2 {f}_{s} ( Z - 1 )}{( Z + 1 )} ) + 1\end{matrix}}\end{matrix}$$

where fₛ is the sampling frequency in hertz.

Coefficients in numerator of H₍ₛ₎ in descending powers of s are Num=[0.001314306 0.1995]. Coefficients in denominator of H₍ₛ₎ in descending powers of s are Den=[0.0000145887966 0.01657845 1]. After applying bilinear function [Numz, Denz]=bilinear (Num, Den, fₛ) to Num [0.001314306 0.1995] and Den [0.0000145887966 0.01657845 1], coefficients in numerator of H_{(z)} in descending powers of z, i.e. Numz [x₀ x₁ x₂] and coefficients in denominator of H_{(z)} in descending powers of z, i.e. Numz [y₀ y₁ y₂] are obtained. Thus, H_{(z)} is obtained as follows:

$${H}_{( z )} = \frac{{x}_{0} + {x}_{1} {Z}^{- 1} + {x}_{2} {Z}^{- 2}}{{y}_{0} + {y}_{1} {Z}^{- 1} + {y}_{2} {Z}^{- 2}} .$$

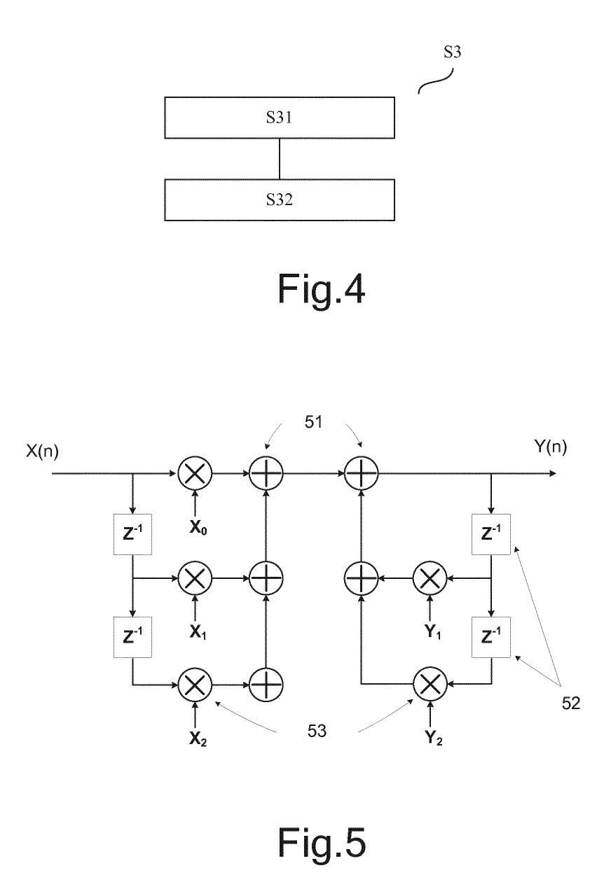

As shown in FIG. 4, step S3 comprises step S31 of selecting the sampling frequency for establishing the junction temperature compensation model.

Coefficients x₀, x₁, x₂, y₀, y₁, y₂ of H_{(z)} are related to the sampling frequency fₛ. That is, with different sampling frequency fₛ, H_{(z)} is different. Therefore, the sampling frequency can be selected by first assuming different sampling frequencies so that different junction temperature compensation models can be established in step S3 and different junction temperatures of the RF power MOSFET can be calculated in step S4, and comparing the different junction temperatures of the RF power MOSFET with a theory temperature value. The frequency resulting in the smallest difference between the calculated junction temperature and the theory temperature value is selected as the sampling frequency for establishing the junction temperature compensation model. The theory temperature value may be obtained in many ways. For example, it may be obtained from analog simulation where the resistors and capacitors are selected and tested in high accuracy though the time cost may be high for doing that.

Based on comparison of simulation results for different sampling frequencies with the theory temperature value, if the sampling frequency for establishing the junction temperature compensation model is selected as 10 KHz, the accuracy in determining the junction temperature of an RF power MOSFET is further improved.

Step S3 further comprises step S32 of selecting the type of 2^{nd} order IIR filter structure for establishing the junction temperature compensation model.

With different types of 2^{nd} order IIR filter structures, the junction temperature compensation models are different. Therefore, the type of 2^{nd} order IIR filter structure for establishing the junction temperature compensation model can be selected by first assuming different types of 2^{nd} order IIR filter structures for establishing the junction temperature compensation model, such as direct form I IIR filter structure, direct form II IIR filter structure, transposed filter structure, etc., and then comparing the different junction temperatures of the RF power MOSFET thus calculated with a theory temperature value. The type of 2^{nd} order IIR filter structure resulting in the smallest difference between the calculated junction temperature and the theory temperature value is selected as the type of 2^{nd} order IIR filter structure for establishing the junction temperature compensation model. The theory temperature value may be obtained in many ways. For example, it may be obtained from analog simulation where the resistors and capacitors are selected and tested in high accuracy though the time cost may be high for doing that.

Based on comparison of simulation results for different types of 2^{nd} order IIR filter structures with the theory temperature value, if the type of 2^{nd} order IIR filter structure for establishing the junction temperature compensation model is selected as direct form II IIR filter structure, the accuracy in determining the junction temperature of an RF power MOSFET is further improved.

FIG. 5 shows an example of a direct form II IIR filter structure selected for establishing the junction temperature compensation model based on the transfer function in time domain of the transient thermal impedance model

$${H}_{( z )} = \frac{{x}_{0} + {x}_{1} {Z}^{- 1} + {x}_{2} {Z}^{- 2}}{{y}_{0} + {y}_{1} {Z}^{- 1} + {y}_{2} {Z}^{- 2}}$$

according to an embodiment of this invention, wherein y₀=1. In FIG. 5, reference sign 53 represents a multiplier, reference sign 51 represents an adder, and reference sign 52 represents a delay element.

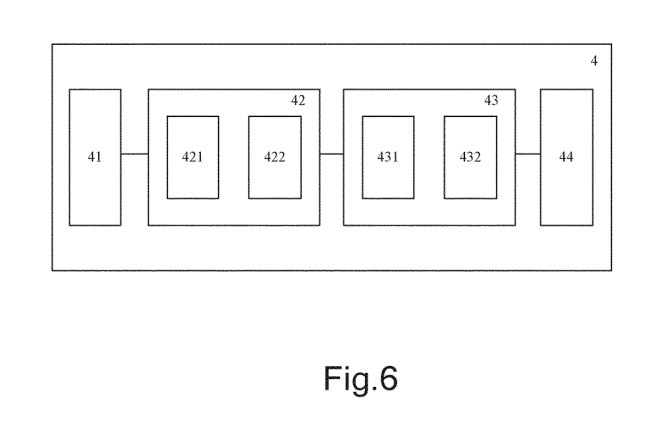

FIG. 6 shows a block figure of an apparatus 4 for calculating the junction temperature of an RF power MOSFET according to an embodiment of this invention. The apparatus 4 comprises a first establishing unit 41, a first calculating unit 42, a second establishing unit 43 and a second calculating unit 44.

The first establishing unit 41 is configured to establish a transient thermal impedance model of the RF power MOSFET in analog domain. The first establishing unit 41 can be realized in many ways. For example, it can be realized as a receipt module for receiving parameters such as R₁, R₂, C₁, C₂, etc. input by an operator according to the product specification made when out of factories, or can be realized as a recognizing module for automatically recognizing the scanned product specification.

The first calculating unit 42 is configured to calculate a transfer function in time domain of the transient thermal impedance model using bilinear transformation.

The second establishing unit 43 is configured to establish a junction temperature compensation model in digital domain based on the transfer function in time domain of the transient thermal impedance model with a sampling frequency and a type of 2^{nd} order IIR filter structure.

The second calculating unit 44 is configured to calculate the junction temperature of the RF power MOSFET by inputting an actual input to the junction temperature compensation model. There are many ways to calculate the junction temperature of the RF power MOSFET in the second calculating unit 44. For example, the second calculating unit 44 may be configured to calculate the junction temperature of the RF power MOSFET by software simulation. As another example, the second calculating unit 44 is configured to calculate the junction temperature of the RF power MOSFET by FPGA.

As shown in FIG. 6, in an embodiment, the first calculating unit 42 comprises a third calculating unit 421 and a converting unit 422. The third calculating unit 421 is configured to calculate a transfer function in frequency domain of the transient thermal impedance model. The converting unit 422 is configured to convert the transfer function in frequency domain of the transient thermal impedance model into the transfer function in time domain of the transient thermal impedance model using bilinear transformation.

Also as shown in FIG. 6, in an embodiment, the second establishing unit 43 comprises a first selecting unit 431 and a second selecting unit 432. The first selecting unit 431 is configured to select the sampling frequency for establishing the junction temperature compensation model. The second selecting unit 432 is configured to select the type of 2^{nd} order IIR filter structure for establishing the junction temperature compensation model.

Each unit in FIG. 6 may be an embedded component which is embedded into the instrument where the RF power MOSFET is incorporated. Or, all the units in FIG. 6 are realized by a device outside the instrument where the RF power MOSFET is incorporated, such as a general computer loaded with corresponding software.

Further, according to an embodiment of this invention, this invention may be embodied as a computer executable program recorded in a computer readable medium and which can be executed by e.g. a general computer to perform a method for calculating the junction temperature of an RF power MOSFET when loaded to the computer, comprising instruction codes of: establishing a transient thermal impedance model of the RF power MOSFET in analog domain; calculating a transfer function in time domain of the transient thermal impedance model using bilinear transformation; establishing a junction temperature compensation model in digital domain based on the transfer function in time domain of the transient thermal impedance model with a sampling frequency and a type of 2^{nd} order IIR filter structure; and calculating the junction temperature of the RF power MOSFET by inputting an actual input to the junction temperature compensation model. The general computer may comprise a CPU, a memory, an input/output interface, etc.

It should be noted that the above-mentioned embodiments illustrated rather than limit the invention and that those skilled in the art would be able to design alternative embodiments without departing from the scope of the appended claims. The embodiments are illustrative rather than restrictive. It is intended that the invention include all modifications and variations to the illustrated and described embodiments within the scope and spirit of the invention. In the claims, any reference signs placed between parentheses shall not be construed as limiting the claim. The word “comprising” does not exclude the presence of elements or steps not listed in a claim or in the description. The word “a” or “an” preceding an element does not exclude the presence of a plurality of such elements. In the device claims enumerating several units, several of these units can be embodied by one and the same item of hardware or software. The usage of the words first, second and third, et cetera, does not indicate any ordering. These words are to be interpreted as names.

1. A method for calculating the junction temperature of an RF power MOSFET, comprising steps of:
establishing a transient thermal impedance model of the RF power MOSFET in analog domain;
calculating a transfer function in time domain of the transient thermal impedance model using bilinear transformation;
selecting a preferable sampling frequency and a preferable type of second order infinite impulse response (IIR) filter structure to establish a junction temperature compensation model in digital domain based on the transfer function in time domain of the transient thermal impedance model; and
calculating the junction temperature of the RF power MOSFET by inputting an actual input to the junction temperature compensation model.

2. The method according to claim 1, wherein the step of calculating a transfer function in time domain of the transient thermal impedance model comprises steps of:
calculating a transfer function in frequency domain of the transient thermal impedance model;
converting the transfer function in frequency domain of the transient thermal impedance model into the transfer function in time domain of the transient thermal impedance model using bilinear transformation.

3. The method according to claim 1, wherein the step of selecting a preferable sampling frequency comprises steps of:
establishing a plurality of junction temperature compensation models with a plurality of sampling frequencies;
calculating a plurality of junction temperatures using the plurality of established junction temperature compensation models; and
selecting the sampling frequency that results in the minimum difference between the predetermined theoretical temperature value and the calculated junction temperatures as the preferable sampling frequency.

4. The method according to claim 1, wherein in the step of selecting the preferable sampling frequency for establishing the junction temperature compensation model, the preferable sampling frequency is selected as 10 KHz.

5. The method according to claim 1, wherein the type of second order IIR filter structure is selected as direct form II IIR filter structure.

6. The method according to claim 1, wherein the step of calculating the junction temperature of the RF power MOSFET is implemented by software simulation.

7. The method according to claim 1, wherein the step of calculating the junction temperature of the RF power MOSFET is implemented by FPGA.

8. An apparatus for calculating the junction temperature of an RF power MOSFET, comprising:
a first establishing unit configured to establish a transient thermal impedance model of the RF power MOSFET in analog domain;
a first calculating unit configured to calculate a transfer function in time domain of the transient thermal impedance model using bilinear transformation;
a second establishing unit configured to establish a junction temperature compensation model in digital domain based on the transfer function in time domain of the transient thermal impedance model by selecting a preferable sampling frequency and a preferable type of a second order infinite impulse response (IIR) filter structure; and
a second calculating unit configured to calculate the junction temperature of the RF power MOSFET by inputting an actual input to the junction temperature compensation model.

9. The apparatus according to claim 8, wherein the first calculating unit comprises:
a third calculating unit configured to calculate a transfer function in frequency domain of the transient thermal impedance model;
a converting unit configured to convert the transfer function in frequency domain of the transient thermal impedance model into the transfer function in time domain of the transient thermal impedance model using bilinear transformation.

10. (canceled)

11. The apparatus according to claim 9, wherein the preferable sampling frequency for establishing the junction temperature compensation model is selected as 10 KHz.

12. The apparatus according to claim 9, wherein the preferable type of second order IIR filter structure for establishing the junction temperature compensation model is selected as direct form II IIR filter structure.

13. The apparatus according to claim 8, wherein the second calculating unit is configured to calculate the junction temperature of the RF power MOSFET by software simulation.

14. The apparatus according to claim 8, wherein the second calculating unit is configured to calculate the junction temperature of the RF power MOSFET by FPGA.

15. A magnetic resonance imaging (MRI) system comprising a MRI amplifier, wherein the MRI system further comprises the apparatus according to claim 8 for calculating the junction temperature of at least one RF power MOSFET used in the MRI amplifier.

16. The method according to claim 1, wherein the step of selecting a preferable type of 2nd order IIR filter structure comprises steps of:
establishing a plurality of junction temperature compensation models with a plurality of types of the second order infinite impulse response (IIR) filter structure;
calculating a plurality of junction temperatures using the plurality of established junction temperature compensation models; and
selecting the type of the second order IIR filter structure that results in the minimum difference between the predetermined theoretical temperature value and the calculated junction temperatures as the preferable type of 2nd order IIR filter structure.
